(19) United States
(12) Patent Application Publication
(10) Pub. No.: US 2015/0280667 A1
(43) Pub. Date: Oct. 1, 2015

(54) Programmable Vacuum Tube Bias Control

(71) Applicant: Norman George Matthews, Pasadena, MD (US)

(72) Inventor: Norman George Matthews, Pasadena, MD (US)

(21) Appl. No.: 14/229,847

(22) Filed: Mar. 29, 2014

(51) Int. Cl. H03G 3/00; H03F 3/28; H03F 3/181

(52) U.S. Cl. CPC H03G 3/007; H03F 3/181; H03F 3/28; H03F 2200/03; H03F 2200/321

(57) ABSTRACT

This invention provides a way for the user of an amplifier to select the class of operation of the output power tubes. A microprocessor monitors the bias conditions and makes the necessary adjustments to set the amplifier in the user selected class of operation. In one embodiment of this invention the user selects the class of operation via a switch. The microprocessor calculates where the plate current should be per the selected class and adjusts the grid voltage until the proper plate current is achieved.

### CROSS REFERENCE

Provisional Patent Application No. 61/828,792

Title: Programmable Vacuum Tube Bias Control Filed on: May 30, 2013

### TECHNICAL FIELD

The invention pertains generally to the fixed biasing of power tubes for push pull audio amplifiers. In most tube amplifiers biasing falls into three categories, class A, class AB and class B. In fixed bias operation a voltage is applied to the grid that is more negative than the Cathode and is used as a means of controlling the current flow from Cathode to Plate. The amount of negative voltage applied to the grid determines the class of operation. In class A operation the tube conducts for a full cycle of the waveform. In class B the tube conducts for half a cycle of the waveform and in class AB the tube conducts for more than half a cycle but less than a full cycle.

### BACKGROUND INFORMATION AND PRIOR ART

For tube guitar amplifiers it is well known that the class of operation has a significant effect on the tone and response of the amplifier. Class A is typically associated with a compressed easily overdriven sound while class AB is associated with a cleaner sound, more headroom and less compression. Class B is associated with odd order distortion as a result of the waveform transitioning from tube to tube but has the greatest efficiency and headroom. Traditionally the class of operation of a fixed bias amplifier is set by the manufacturer. The grid voltage is not controllable by the user except that in some cases a potentiometer is provided inside the chassis to allow a technician to make slight changes in the grid voltage to account for tube variations.

### DESCRIPTION OF THE DRAWINGS

FIG. 1 shows schematically the implementation of a programmable vacuum tube bias control according to one embodiment of this invention.

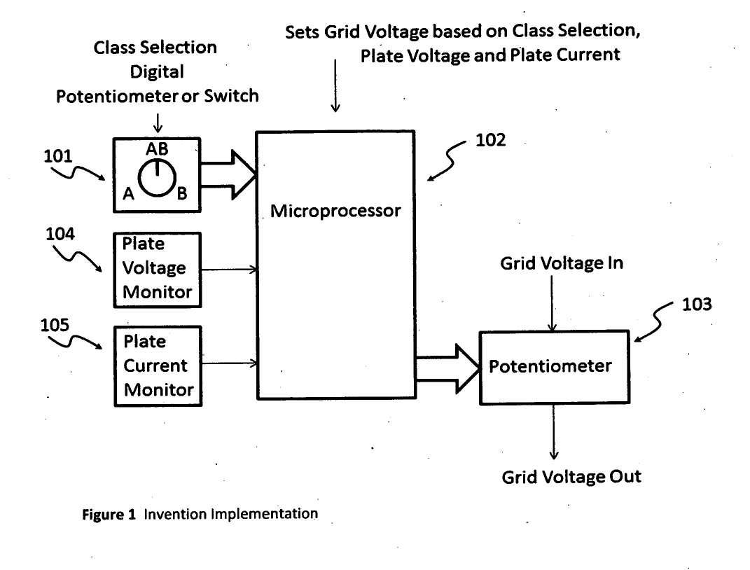

FIG. 2 shows typical vacuum tube plate characteristics along with the maximum tube dissipation and load lines for different classes of operation.

FIG. 3 flow chart of the software code for one embodiment of this invention.

### DETAILED DESCRIPTION OF INVENTION

In this patent the user of the amplifier selects the class of operation via a digital potentiometer or switch (101). A microprocessor (102) monitors the plate voltage (104) and plate current (105) and calculates the appropriate grid voltage to set the amplifier in the selected class of operation via a potentiometer (103).

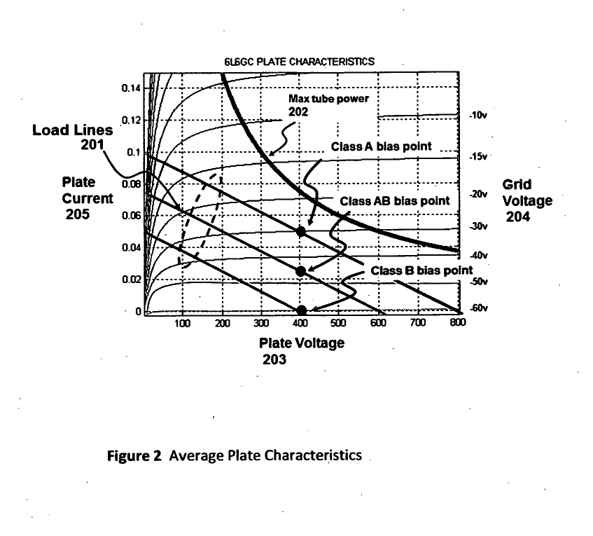

FIG. 2 shows a typical set of grid voltage curves for a pentode power tube. Drawn on this figure are the load lines (201) for different bias classes and the maximum power curve (202). In this illustration the plate voltage (203) is held constant at 400 v and the load line is moved based on the grid voltage (204). The corresponding plate current (205) is read off the y axis. For class A the bias point is approximately at the midpoint of the load curve. For class AB the bias point is approximately halfway between the midpoint and where the load curve intersects the x-axis. For Class B the bias point is approximately at the point where the load curve intersects the x-axis. In this invention the microprocessor (102) monitors the plate voltage and plate current and adjusts the grid voltage to set the bias point at the selected class of operation.

In another embodiment of this invention the plate voltage as well as the grid voltage is controlled by the microprocessor. By controlling the plate voltage an additional degree of control over the bias point is possible. By controlling both the grid and plate voltage the bias point as well as tube power dissipation can be controlled.

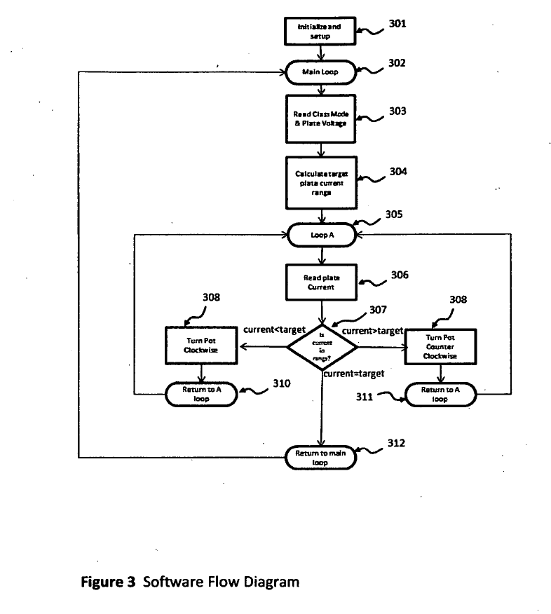

FIG. 3 is a flow diagram for one embodiment of this invention. The first step (301) is to initialize the state of all inputs and outputs. The next step (302) is to set up the main loop. The first step in the main loop is to read the mode switch and the plate voltage (303). Knowing the mode and plate voltage, the appropriate range for the plate current is calculated (304). The next step is to set up the adjustment loop (305). First the plate current is read (306) and then a decision is made (307) to either leave the current as is if it is in the calculated target range or adjust the potentiometer clockwise (308) or counter clockwise (309) to set the grid voltage so the plate current is in the appropriate range. After adjusting the potentiometer the program returns to the beginning of the adjustment loop (310) and (311) to read the plate current after adjustment and repeat the procedure. Once the target plate current is reached (312) the program returns to the main loop to continue monitoring the mode switch, plate voltage and plate current.

1. A method to control the bias point of a vacuum tube amplifier using a microprocessor to monitor the plate voltage and current and make adjustments based on the selected class of operation.

2. The method according to claim one where the user selects the bias class via a digital or analog switch.

3. The method according to claim one where the microprocessor controls the grid voltage via a motorized potentiometer.

4. The method according to claim one where the microprocessor controls the grid voltage via a digital potentiometer.

5. The method according to claim one where the microprocessor controls the plate voltage via a motorized potentiometer.

6. The method according to claim one where the microprocessor controls the plate voltage via a digital potentiometer.
